(19) United States
(12) Patent Application Publication
(10) Pub. No.: US 2026/0236817 A1
(43) Pub. Date: Aug. 13, 2026

(54) TUNABLE CAPACITOR FOR SUPERCONDUCTING QUBITS

(71) Applicant: COLORADO SCHOOL OF MINES, Golden, CO (US)

(72) Inventors: Eliot Kapit, Golden, CO (US); Nicholas Materise, Golden, CO (US); Javad Shabani, New York City, NY (US)

(21) Appl. No.: 19/386,018

(22) Filed: Nov. 11, 2025

Related U.S. Application Data
(63) Continuation of application No. 17/564,789, filed on Dec. 29, 2021, now Pat. No. 12,468,971.
(60) Provisional application No. 63/132,831, filed on Dec. 31, 2020.

(51) Int. Cl. G06N 10/40; H10N 60/85

(52) U.S. Cl. CPC G06N 10/40; H10N 60/85

(57) ABSTRACT

An exemplary tunable capacitor in a quantum system includes a pair of qubits, and a capacitive coupling element coupled between the pair of qubits. The capacitive coupling element includes a plurality of gate terminals. The capacitive coupling element is configured to receive a respective gate voltage at each of the plurality of gate terminals and to adjust a capacitance of the capacitive coupling element in response to the respective gate voltage received at each of the plurality of gate terminals. The capacitance of the capacitive coupling element is configured to control a coupling strength between the pair of qubits.

### CROSS-REFERENCE TO RELATED APPLICATIONS

This application is a continuation of U.S. patent application Ser. No. 17/564,789, filed Dec. 29, 2021, entitled “Tunable Capacitor for Superconducting Qubits,” issued Nov. 11, 2025 as U.S. Pat. No. 12,468,971 B2, which claims priority to U.S. Provisional Application No. 63/132,831, filed Dec. 31, 2020, entitled “Tunable Capacitor for Superconducting Qubits Using an InAs/InGaAs Heterostructure,” each of which is incorporated by reference herein, in the entirety and for all purposes.

### BACKGROUND

Tunable couplers for superconducting qubits, once a long-term investment in future quantum computers and a direction towards improving two-qubit gate fidelities are now a centerpiece of large qubit arrays. The recent quantum supremacy demonstration owes its success in part to the two qubit gate fidelities across the chip facilitated by fast, tunable couplers. Frequently realized as a mutual inductance or effective capacitance between nearest-neighbor qubits and tuned by flux-biased superconducting quantum interference devices (SQUIDs), these couplers naturally integrate with both fixed and flux-tunable superconducting qubits.

Recent advancements in semiconductor-superconductor junctions as gate-tunable Josephson junctions have led to new proposals and realizations of coupling schemes to superconducting storage units and readout buses. Unlike their transmon counterparts, these hybrid systems employ various III-V semiconductor materials with properties tunable in both fabrication and with external electric fields as opposed to the canonical, fixed fabrication Al/Al2O3 and Nb-based device stacks that rely on external current sources for tuning.

As with prior attempts to improve coherence with new materials, there are challenges in realizing high coherence gatemon qubits, where an applied electric potential depletes a superconductor-semiconductor-superconductor junction. Recent dielectric loss studies of III-V materials, specifically Al/GaAs/Al trilayers, suggest that the piezoelectricity of GaAs can contribute to higher losses compared to sapphire or silicon substrates. Apart from the aforementioned experimental results for GaAs, there have been no other studies that have measured the loss in III-V materials at single photon powers and millikelvin temperatures. A solution that addresses both the issue of realizing a fast, tunable coupler and quantifying its potential as an additional source of dielectric loss has proven difficult.

### BRIEF DESCRIPTION OF THE DRAWINGS

FIG. 1 is a schematic diagram of a 2-qubit quantum system in accordance with embodiments of the present disclosure.

FIG. 2 is a cross-sectional diagram of capacitive coupling element in accordance with embodiments of the disclosure.

FIG. 3 shows electron concentrations on a logarithmic scale with source-drain bias for fully conducting and fully depleted operating points, and for the fully depleted limit with all gates biased.

FIG. 4 shows capacitance and conductance matrices computed for fully depleted and fully conducting states.

FIG. 5 is a false color geometry image of two transmon qubits with a capacitive coupler.

FIG. 6 illustrates an electric field norm for eigenmode solutions.

FIGS. 7A and 7B illustrate a circuit model for a total 2DEG coupler with gates and a pair of transmon qubits, compared with a simplified circuit used in derivation of the charge matrix.

### DETAILED DESCRIPTION

This disclosure includes examples of a tunable coupler to control interactions between solid-state qubits, including interactions between solid-sate qubits in a single, two-dimensional (2D) layer, interactions between three-dimensional (3D) cavities, or any combination thereof. In some examples, the solid-state qubits may include superconducting qubit, quantum-dot qubits, flux-qubits, 3D cavities, or any other type of solid-state qubits. The tunable coupler may include a capacitor with source and drain terminals each connected to a respective qubit, and a plurality of gate terminals that are selectively enabled to adjust or control a capacitance. In some examples, adoption of fast, parametric coupling elements may improve the performance of superconducting qubits. A low loss, high contrast coupler may be useful in scaling up quantum computing systems. In some examples, the gate-tunable coupler may be formed using a two-dimensional electron gas in an InAs/InGaAs heterostructure. Such an implementation may yield an on/off ratio of over two orders of magnitude.

The gate voltage-controlled capacitive coupling element between neighboring superconducting qubits described herein may include a pair of fixed air-gap capacitors with a single, effective capacitance that is tuned by a collection of gates (e.g., metal oxide) that deplete a two-dimensional electron gas (2DEG) in a semiconductor heterostructure (e.g., InAs/InGaAs heterostructure). The described coupling element relying on tuning of electric fields to control qubit interactions may be a replacement for a flux-biased superconducting quantum interference device (SQUID)-based inductive couplers (which rely on tuning of electromagnetic fields to control qubit interactions).

Air-gap capacitors isolate the tuning elements, namely the gates, from the qubits, which may reduce stray electric fields on the neighboring qubits as compared with flux-biased SQUID devices, where stray magnetic fields lead to crosstalk between qubits. In some examples, implementations other than the air-gap capacitors may be realized to achieve a tunable capacitor without departing from the scope of the disclosure.

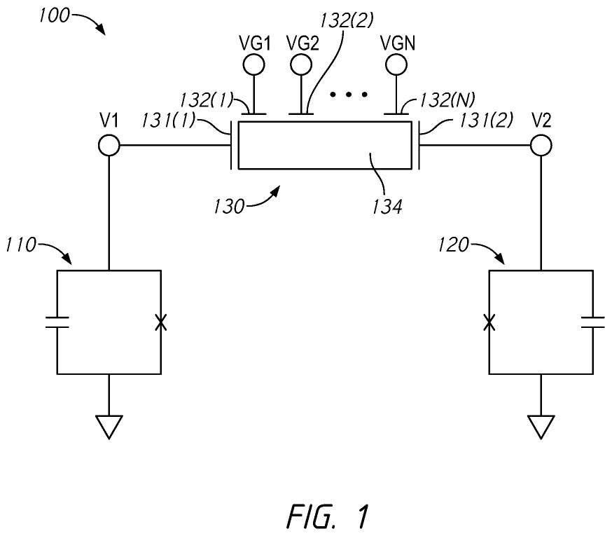

FIG. 1 is a schematic diagram of a 2-qubit quantum system 100 in accordance with embodiments of the present disclosure. The system 100 includes a first qubit 110, a second qubit 120, and a capacitive coupling element 130. The first qubit 110 and the second qubit 120 may form a pair of qubits for which the capacitive coupling element 130 is used to control coupling there between. The first qubit 110 and the second qubit 120 may include any type of transmon qubit.

The capacitive coupling element 130 may include source/drain terminals 131(1), 131(2) at each end that are coupled to the nodes providing the V1 and V2 voltages, respectively. The capacitive coupling element 130 may further include multiple gate terminals 132(1)-132(N), where N is a positive integer. In some examples, N may be equal to 3, 4, 5, etc. In some examples, N may be less than 10. In some examples, the capacitive coupling element 130 may include only two gate terminals. The gate terminals 132(1)-132(N) may be configured to control the conductive properties within the dielectric material 134 to control the effective capacitance of the capacitive coupling element 130. Each of the gate terminals 132(1)-132(N) may be configured to receive a respective gate voltage VG1-VGN. Collectively, the respective VG1-VGN gate voltages may be selected to tune a particular effective capacitance of the capacitive coupling element 130 between the source/drain terminals 131(1), 131(2).

In operation, the VG1-VGN gate voltages may be selected to control coupling between the first qubit 110 and the second qubit 120 by adjusting the capacitance of the capacitive coupling element 130. That is, as the VG1-VGN gate voltages increase, the coupling between the first qubit 110 and the second qubit 120 become tighter, because the capacitance increases within the capacitive coupling element. Implementation of the capacitive coupling element 130 may be a replacement for a flux-biased SQUID-based inductive couplers, and may reduce crosstalk between the field controlling the coupler and the qubits, particularly if the qubits are tunable with magnetic flux.

In some examples, alternatively or additionally, the capacitive coupling element may be configured to adjust the capacitance in response to the alternating-current (AC) fields to perform parametric operations. In some examples, first and second qubits 110 and 120 and the capacitive coupling element 130 may be included in a small logical qubit device. In some examples, one of the pair of qubits may be a solid-state qubit and the other may be a three-dimensional cavity. In some examples, the capacitive coupling element may be configured to adjust the capacitance of the capacitive coupling element to route a signal between the first and qubits 110 and 120. In a multi-qubit architecture on a chip with multiple ones of the tunable elements, the tunable elements may be configured to route signals around the chip for any purpose.

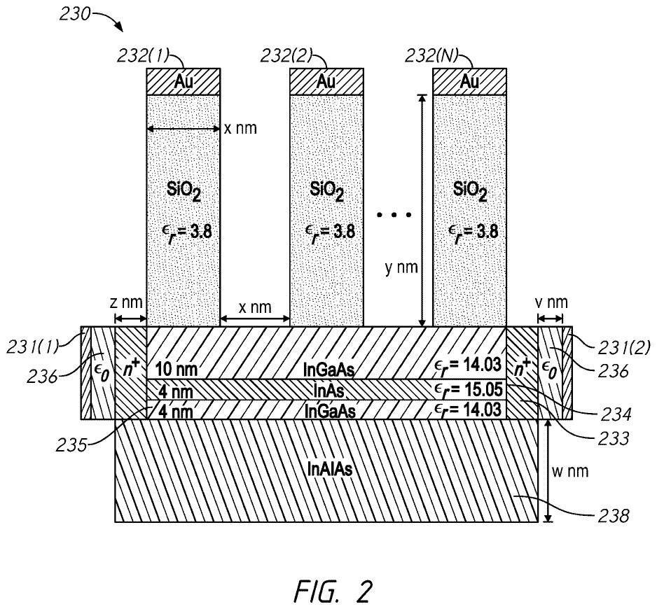

FIG. 2 is a cross-sectional diagram of capacitive coupling element 230 in accordance with embodiments of the disclosure. The capacitive coupling element 130 of FIG. 1 may implement the capacitive coupling element 230 in some examples. The capacitive coupling element 230 may include source/drain terminals 231(1), 231(2) at each end. The capacitive coupling element 230 may further include multiple gate terminals 232(1)-232(N) (e.g., Au and SiO₂), where N is a positive integer. In some examples, N may be equal to 3, 4, 5, etc. In some examples, N may be less than 10. In some examples, the capacitive coupling element 230 may include only two gate terminals. In some examples, the gate terminals 232(1)-232(N) may have a width of X nm and height of Y nm. In some examples, X may be greater than Y. In some examples, X is twice as great as Y. The distances between adjacent gate terminals 232(1)-232(N) may be the same as the width, which is X nm.

The gate terminals 232(1)-232(N) may be configured to control the conductive properties within the dielectric material 234 (e.g., InAs) and 235 (e.g., InGaAs) formed on the substrate 238 (e.g., InAlAs) to control the effective capacitance of the capacitive coupling element 230. The substrate 238 may have a height of W nm. Each of the gate terminals 232(1)-232(N) may be configured to receive a respective gate voltage VG1-VGN. Collectively, the respective VG1-VGN gate voltages may be selected to tune a particular effective capacitance of the capacitive coupling element 230 between the source/drain terminals 231(1)-232(2).

The dielectric material 234 and 235 may be buffered on each side by respective n+ regions 233 and air-gap regions 236. The air gap regions 236 may be in contact with the source/drain terminals 231(1), 231(2). The n+ region 233 may include highly doped n-type InAs. The n+ regions 233 may also be formed on the substrate 238, and may have a width of Z nm. The air-gap regions 236 may have a width of V nm. In some examples, V is less than Z. In some examples, Z is 3, 4, or 5 times greater than V. In some examples, X is four times greater than Z.

Specific, non-limiting examples of the capacitive coupling element are described herein. From the foregoing it will be appreciated that, although specific embodiments of the disclosure have been described herein for purposes of illustration, various modifications may be made without deviating from the spirit and scope of the disclosure. Accordingly, the disclosure is not limited except as by the appended claims.

### Tunable Capacitor for Superconducting Qubits Using an INAS/INGAAS Heterostructure

Adoption of fast, parametric coupling elements has improved the performance of superconducting qubits, enabling recent demonstrations of a quantum advantage in randomized sampling problems. The development of low loss, high contrast couplers is critical for scaling up these systems. We present a blueprint for a gate-tunable coupler realized with a two-dimensional electron gas in an InAs/InGaAs heterostructure. Our numerical simulations yield an on/off ratio of over two orders of magnitude. We give an estimate of the dielectric-limited loss from the inclusion of the coupler in a two qubit system.

### I. INTRODUCTION

Tunable couplers for superconducting qubits, once a long-term investment in future quantum computers and a direction towards improving two-qubit gate fidelities [1,2], are now a centerpiece of large qubit arrays. The recent quantum supremacy demonstration [3] owes its success in part to the two-qubit gate fidelities across the chip facilitated by fast, tunable couplers. Frequently realized as a mutual inductance or effective capacitance between nearest-neighbor qubits and tuned by flux-biased superconducting quantum interference devices (SQUIDs), these couplers naturally integrate with both fixed and flux-tunable superconducting qubits [4].

Recent advancements in semiconductor-superconductor junctions as gate-tunable Josephson junctions have led to new proposals and realizations of coupling schemes to superconducting storage units [5] and readout buses [6]. Unlike their transmon [7] counterparts, these hybrid systems employ various III-V semiconductor materials with properties tunable in both fabrication and with external electric fields as opposed to the canonical, fixed fabrication Al/Al₂O₃ and Nb-based device stacks that rely on external current sources for tuning [8].

As with prior attempts to improve coherence with new materials, there are challenges in realizing high coherence gatemon [9] qubits, where an applied electric potential depletes a superconductor-semiconductor-superconductor junction. Recent dielectric loss studies of III-V materials, specifically Al/GaAs/Al trilayers, suggest that the piezoelectricity of GaAs can contribute to higher losses compared to sapphire or silicon substrates [10,11]. Apart from the aforementioned experimental results for GaAs, there have been no other studies to our knowledge that have measured the loss in III-V materials at single photon powers and millikelvin temperatures.

To address both issues of realizing a fast, tunable coupler and quantifying its potential as an additional source of dielectric loss, we propose the following. First, we propose a novel voltage-controlled capacitive coupling element between neighboring superconducting qubits. Composed of a pair of fixed air-gap capacitors and a single, effective capacitance tuned by a collection of metal-oxide gates that deplete a two dimensional electron gas (2DEG) in an InAs/InGaAs semiconductor heterostructure, the coupler is a potential replacement for SQUID-based inductive couplers [12].

Air-gap capacitors isolate the tuning elements, namely the gates, from the qubits, minimizing stray electric fields on the neighboring qubits. This is an improvement over the SQUID-based couplers, where stray magnetic fields can lead to classical cross-talk between qubits [13]. We suspect that the 2DEG coupler will introduce more charge noise than the inductive couplers, though transmon qubits are first order insensitive to charge noise and we focus on their integration with such qubits [7].

To resolve the latter issue of quantifying the dielectric loss introduced by the 2DEG coupler, we performed measurements of microwave conductivity at single photon powers and millikelvin temperatures.

The structure of the paper is as follows. In Section II, we outline our numerical models of the 2DEG coupler, starting with semiconductor electron density calculations, then detailing our numerical models for dielectric loss. Section III provides ANSYS HFSS simulations of a prototypical two transmon qubit circuit coupled to a lumped impedance representing the 2DEG coupler. Here, we compute the lowest order electromagnetic eigenmodes of the device and apply energy participation ratio techniques to extract the Hamiltonian matrix elements in the dispersive regime. We extend these calculations to extract the charge-charge matrix elements corresponding to the dominant capacitive interaction between the two transmon qubits mediated by the 2DEG coupler. Final discussions, observations, and a summary of results are given in Section IV.

### II. COUPLER MODELING

### A. Semiconductor 2Deg Calculations

As a first step in estimating the capacitance of the 2DEG coupler, we computed the electron concentration in COMSOL Multiphysics with the Semiconductor Module [14]. Equilibrium solutions to the drift-diffusion equations with Fermi-Dirac statistics revealed regions of high depletion under the gates when applying negative voltages on the order of a few volts, overcoming the barrier of the Au electrode on SiO₂ (2.98 eV) [15].

We modeled the InGaAs/InAs/InGaAs heterostructure by specifying electron and hole effective conduction band masses

$${m}_{n ( p ) , c}^{*} ,$$

low-field mobilities

$${μ}_{n ( p )}^{If} ,$$

band gap energies E_{g}, conduction band offsets ΔE_{c} between neighboring semiconductors, dielectric constants εᵣ, and effective densities of states for the conduction and valence bands N_{c(v)}. Taking the electron affinity χ for InAs as given from the COMSOL material library, we calculated the remaining affinities using Anderson's affinity rule [16].

TABLE I
Materials parameters used in the
COMSOL Semiconductor Module calculations

| | InAs | InGaAs | INAlAs |
|---|---|---|---|
| E_{g} [eV] | 0.354 | 0.473 | 0.752 |
| ΔE_{c} [eV] | — | 0.200 | 0.201 |
| εᵣ | 15.15 | 14.03 | 13.13 |
| N_{c(v)} [cm⁻³] | 6.6e18 | 1.4e17 | 2.1e17 |
| | (8.73e16) | (6.4e18) | (7.8e18) |
| X [eV] | 4.9 | 4.7 | 4.5 |
| ${μ}_{n ( p )}^{If} [ {cm}^{2} {V}^{- 1} {s}^{- 1} ]$ | 14.4e3 (500) | 14.4e3 (450) | 14.e3 (384) |
| ${m}_{n ( p ) , c}^{*} [ {m}_{0} ]$ | 0.023 (1.00) | 0.03 (0.25) | 0.04 (0.31) |

Table I gives a summary of the materials parameters used in the semiconductor simulations. InGaAs and InAlAs abbreviate In_{0.81}Ga_{0.19}As and In_{0.81}Al_{0.19}As; m₀ corresponds to the rest mass of an electron 0.511 MeV c⁻². Out-of-plane effective electron and hole masses of InAs are set to m₀ in the model to simulate 2DEG confinement. Electron mobilities for InAs, InGaAs, and InAlAs are all set to the same value extracted from measurements of a similar device at millikelvin temperatures [17]. See Annex A for detailed calculations of the InₓGa₁₋ₓAs and InₓA1₁₋ₓAs parameters as a function of the compositional parameter (x).

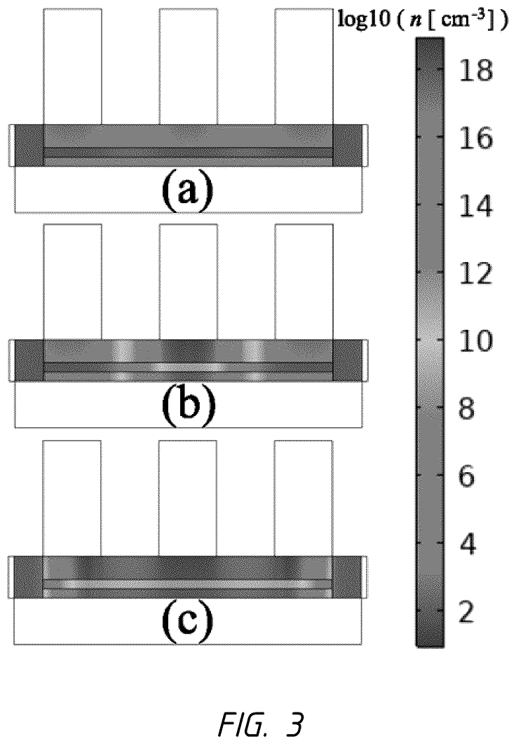

FIG. 3 shows electron concentrations [cm⁻³] on a base-10 logarithmic scale with source-drain bias V_{sd}=+5 mV−(−5 mV)=10 mV for (a) the fully conducting V_{g}=0 V and (b) fully depleted V_{g}=−3 V operating points, with V_{g} applied to the center gate and the other two gates grounded; and (c) electron concentrations for the fully depleted limit with all gates biased to −3 V. The electron concentration is absent in the regions where we applied the Electric Charge Conservation equations without solving for n, i.e., in the SiO₂, InAlAs, and air regions. The vertical axis scales by a factor of four relative to the horizontal.

In setting up our electron concentrations calculations, we input the geometry in FIG. 2 using the native COMSOL CAD editor. Next, we assigned material properties to each domain using the values from Table I. Source and drain contacts in FIG. 1 were modeled as ideal ohmic contacts, while the gates were ideal Schottky contacts with a barrier height qφ_{B}=2.98 eV for Au on SiO₂ [15]. Terminal labels follow the conventions established in FIG. 1 for the node voltages V1, V2 and VG1-VGN.

We selected the density gradient discretization scheme [18] in COMSOL to accurately model the quantum confinement effects in the 2DEG without resorting to a self-consistent Schrödinger-Poisson equation calculation. The density gradients modify the equilibrium electron (n) and hole (p) concentrations as [14]

$$n = {N}_{c} {F}_{1 / 2} ( \frac{{E}_{fn} - {E}_{c} + {qV}_{n}^{DG}}{{k}_{B} T} ) \qquad ( 1 )$$

$$n = {N}_{v} {F}_{1 / 2} ( \frac{{E}_{v} - {E}_{fp} + {qV}_{p}^{DG}}{{k}_{B} T} ) \qquad ( 2 )$$

$${N}_{c ( v )} = {( \frac{2 {m}_{n ( p )}^{*} π {k}_{B} T}{{h}^{2}} )}^{3 / 2} , \qquad ( 3 )$$

where E_{c(v)} is a given material's conduction (valence) band edge, E_{fn(p)} are the electron (hole) quasi-Fermi level energies, F_{1/2}(η) is the Fermi-Dirac integral [19], k_{B} is Boltzmann's constant, T is the temperature of the system, and q is the charge on the electron or hole.

We define the quantum potentials

$${V}_{n ( p )}^{D G}$$

in terms of the density gradients [14]

$$∇ \cdot ( {b}_{n} ∇ \sqrt{n} ) = \frac{1}{2} \sqrt{n} {V}_{n}^{DG} \qquad ( 4 )$$

$$∇ \cdot ( {b}_{p} ∇ \sqrt{p} ) = \frac{1}{2} \sqrt{p} {V}_{p}^{DG} , \qquad ( 5 )$$

with the density gradient tensors bₙ₍ₚ₎ for electrons (holes) expressed in terms of the effective mass tensors m*ₙ₍ₚ₎

$${b}_{n} = {\frac{{ℏ}^{2}}{12 q} [ {m}_{n} ]}^{- 1} \qquad ( 6 )$$

$${b}_{p} = {\frac{{ℏ}^{2}}{12 q} [ {m}_{p} ]}^{- 1} . \qquad ( 7 )$$

Note the distinction between the scalar effective masses m*ₙ₍ₚ₎ and, the effective mass tensors m*ₙ₍ₚ₎. Anisotropy in the effective mass tensors allows us to model the quantum confinement of the 2DEG by constraining electron movement to one plane.

For the remaining materials, InAlAs, SiO₂, and air, we used the Electric Charge Conservation interface, only adding the following constitutive relations for the dielectric in terms of the electric permittivity tensor ε for each material [14]

$$D = {ε}_{0} ε E , \qquad ( 8 )$$

where D is the electric displacement field, co is the permittivity of free space, and E is the electric field. By modeling these regions as pure dielectrics, we reduce some of the computational cost of our simulations and correctly model the pure dielectrics, e.g., air and oxide layers.

### B. Electrostatic Capacitance Matrix Calculations

Following the semiconductor calculations described in the previous section, we developed a simplified model to extract the capacitance and conductance matrices. This simplified model replaced regions with high electron concentration with perfect electric conductors and regions with low electron concentration with pure dielectrics. The COMSOL Electrostatics Interface defines the Maxwell Capacitance Matrix C in terms of the charges and voltages on each node of an N-terminal network as [20]

$$( \begin{matrix}{Q}_{1} \\ {Q}_{2} \\ ⋮ \\ {Q}_{N}\end{matrix} ) = ( \begin{matrix}{C}_{11} & {C}_{12} & … & {C}_{1 N} \\ {C}_{21} & {C}_{22} & … & {C}_{2 N} \\ ⋮ & ⋮ & & ⋮ \\ {C}_{N 1} & {C}_{N 2} & … & {C}_{NN}\end{matrix} ) ( \begin{matrix}{V}_{1} \\ {V}_{2} \\ ⋮ \\ {V}_{N}\end{matrix} ) , \qquad ( 9 )$$

where Qᵢ and Vᵢ are the charges and voltages on the i-th terminal.

The charges and voltages follow from solutions to Poisson's equation, and the charge continuity equation. In two dimensions these equations combine to give [20]

$$- ∇ \cdot d ( {ε}_{0} ∇ V - P ) = ρ , \qquad ( 10 )$$

where V is the electric potential, P is the polarization vector, p is the space charge density, and d is the out-of-plane thickness. This model is an approximation of the electron densities from the two-dimensional semiconductor interface calculations from the previous section, with d=5 μm.

We set the boundaries of domains representing perfect electric conductors as floating potential boundary conditions and define terminals as ohmic contacts on the corresponding dielectrics in FIG. 2, the schematic of the device as modeled in COM SOL multi-physics [20], Regions labeled n+ refer to highly doped n-type InAs, ε₀ (236) refers to air-gapped regions, and 231(1), 232(2) are the source/drain terminals. Gold electrodes deposited on Sᵢ0₂ define the gate terminals 232(1)-232(N). We scaled the vertical dimensions by factor of four relative to the horizontal to enhance the InGaAs/InAs active region. Not shown or modeled is a several micron thick InP substrate.

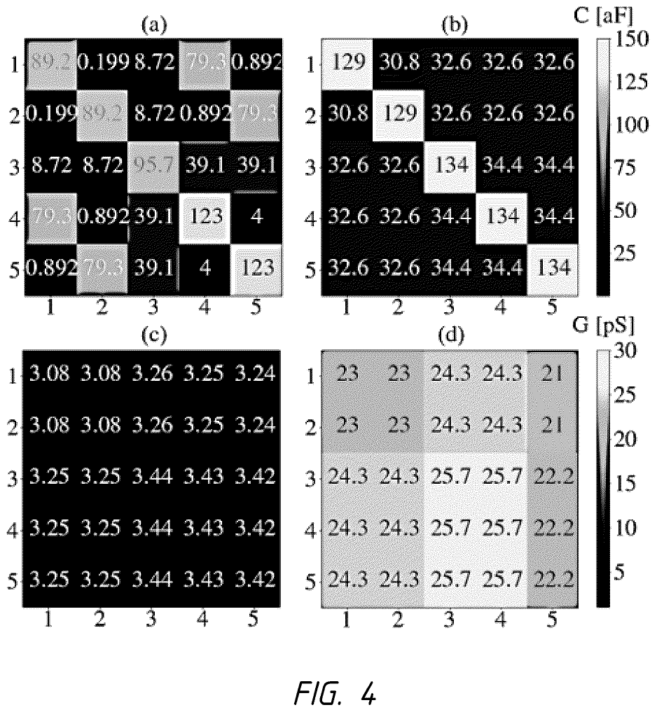

In the fully conducting and depleted limits (V_{g}=0 V and V_{g}=−3 V), we computed the capacitance matrices in FIGS. 4 (a) and (b). The matrix elements of interest, C₁₂=C₂₁ represent the effective capacitance between the source and drain terminals. These terminals form capacitive contacts with any pair of qubits. The tuning ratio r, or on/off contrast of the 2DEG coupler is given by r=C_{12,conducting}/C_{12,depleted}≈160.

### C. Electric Currents Admittance Matrix Calculations

To extract the conductance and verify the capacitance of the device, we used the AC/DC Electric Currents Interface, computing the admittance matrix Y defined in terms of the N terminal voltages Vᵢ and currents Iᵢ [20]

$$( \begin{matrix}{V}_{1} \\ {V}_{2} \\ ⋮ \\ {V}_{N}\end{matrix} ) = ( \begin{matrix}{Y}_{11} & {Y}_{12} & … & {Y}_{1 N} \\ {Y}_{21} & {Y}_{22} & … & {Y}_{2 N} \\ ⋮ & ⋮ & & ⋮ \\ {Y}_{N 1} & {Y}_{N 2} & … & {Y}_{NN}\end{matrix} ) ( \begin{matrix}{I}_{1} \\ {I}_{2} \\ ⋮ \\ {I}_{N}\end{matrix} ) \qquad ( 11 )$$

In the frequency domain, the voltages and currents become phasors of the form \tilde{V}e^{iωt} and Ĩe^{iωt}, with the admittance matrix given by

$$Y = G + i ω C , \qquad ( 12 )$$

where G and C are the conductance and capacitance matrices, i=\sqrt{−1}, and w is the angular frequency [20],

Both matrices are symmetric for our linear, five-terminal device in FIGS. 4 (a)-(d), In general, these matrices they need not be symmetric, e.g., some nonlinear networks such as circulators have nonreciprocal admittance matrices. In the linear case, the Electric Currents Interface in COMSOL computes the currents and voltages in Eq. (11) by solving the time harmonic equations [20]

$$∇ \cdot ( σ E + {J}_{e} ) + i ω ρ = 0 , \qquad ( 13 )$$

$$∇ \cdot D = ρ , \qquad ( 14 )$$

where E is the electric field, Jₑ is the externally generated electric current density, σ is the electrical conductivity, and p is the electric space charge density. We applied the same approach as in the electrostatic calculations, extracting the conductance matrix in the fully depleted and conducting limits of the device.

### D. Dielectric Loss Model

### 1. TLS Loss Model

2. Estimation of Total Loss from Participation Ratios

Following the procedure developed by [21] and recently by [22], we write the relaxation time T₁ at a given angular frequency ω as a function of the dielectric materials properties and geometric factors [22]

$${T}_{1}^{- 1} = \frac{ω}{Q} = ω {\sum }_{j} \frac{{p}_{j}}{{Q}_{j}} + {Γ}_{0} \qquad ( 15 )$$

$${Q}_{j}^{- 1} = tan {δ}_{j} \qquad ( 16 )$$

$${p}_{j} = \frac{{t}_{j} {\int }_{{S}_{j}} {ε}_{0} {ε}_{1 , j} {\vert E \vert}^{2} dS}{{W}_{e}} \qquad ( 17 )$$

where Wₑ is the electric field energy density for the entire geometry S, [symbol] are the quality factors, tan δⱼ are the loss tangents, ε_{1,j} are the real parts of the dielectric function, pⱼ are the participation ratios, and tⱼ are the thicknesses of the layers associated with the j-th surface Sⱼ.

The participation ratios give the fraction of the electrical energy stored in a given surface Sⱼ relative to the total electrical energy stored in the entire device geometry; i.e., S=∪ⱼSⱼ. The last term in Eq. (15), Γ₀, includes all other loss mechanisms contributing to T₁ besides dielectric loss [22], Note, these participation ratios differ from those referred to in subsequent calculations involving energy participation ratios corresponding to a given mode rather than a particular surface.

TABLE II
Participation ratios pⱼ, dielectric loss tangents tanδⱼ,
layer thicknesses tⱼ, and estimated dielectric-loss-limited T_{1,j}

| | tⱼ [nm] | pⱼ | $tan {δ}_{j}^{*}$ | T₁ [μs] |
|---|---|---|---|---|
| InGaAs (Top) | 10 | 2.08E−5 | 4.8E−5 | 3190 |
| InAs | 4 | 3.18E−5 | 4.8E−5 | 20800 |
| InGaAs (Bottom) | 4 | 2.86E−5 | 4.8E−5 | 23200 |
| InAlAs | 20 | 5.64E−4 | 4.8E−5 | 1180 |
| SiO₂ [23] | 50 | 4.44E−3 | 2.00E−5 | 3.58 |
| Total | | | | 3.57 |

Table II gives participation ratios pⱼ, dielectric loss tangents tan δⱼ, layer thicknesses tⱼ, and estimated dielectric-loss-limited T₁ⱼ. All T_{1,j} times referenced to a qubit frequency of ω/2π=5 GHz and

$$tan {δ}_{j}^{*}$$

indicates that in the absence of reliable loss tangent data for InAs, InGaAs, and InAlAs, we used the power-independent loss lower bound for GaAs at 12 mK as a best estimate [10].

### III. INTEGRATION WITH CIRCUIT QED

### A. Two Qubit Coupler

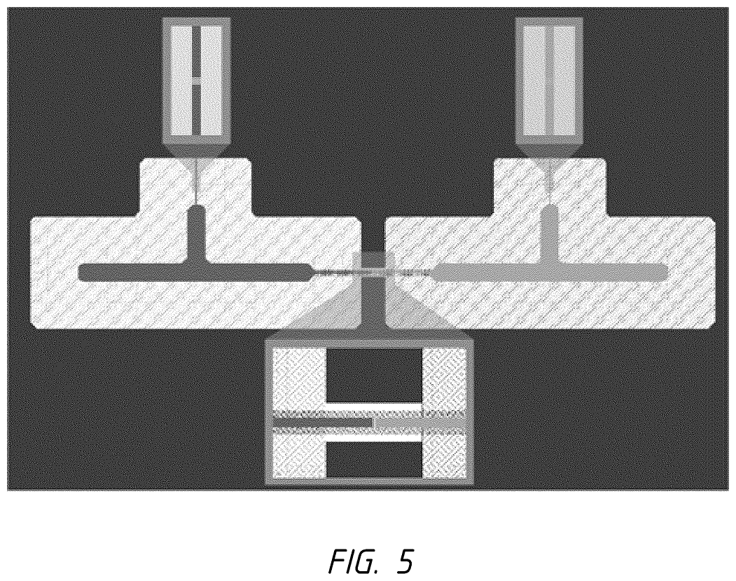

FIG. 5 is a false color geometry image of two transmon qubits with the capacitive coupler in between used in the HFSS simulations. Lumped impedances defined in the gold regions of the insets, represent the linear response of the Josephson junctions and capacitive coupling element in the HFSS model.

In FIG. 5 we have a microwave circuit model of two transmon qubits coupled by a lumped impedance Z_{JJc}(ω)=(R⁻¹+iωC)⁻¹, where R and C take the values of R₁₂ and C₁₂ in either the fully conducting or fully depleted limits of the 2DEG coupler.

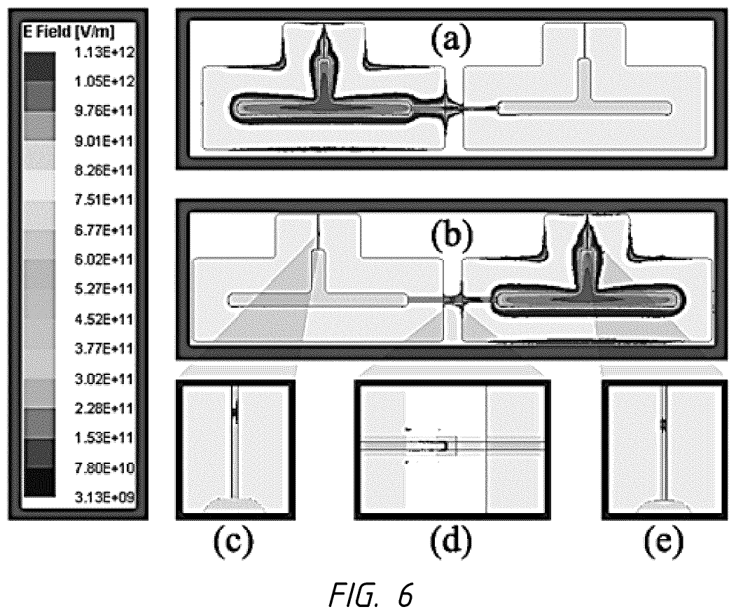

FIG. 6 illustrates the electric field norm for the first three eigenmode solutions computed with HFSS: (a) 5.9 GHZ, (b) 6.1 GHZ, and (c-e) 8.6 GHZ, and magnified views of (c) qubit 1, (d) coupling element, and (e) qubit 2 electric field intensities for the third mode in the fully depleted limit of the coupler. Using ANSYS Electronics Desktop (formerly HFSS), we computed the lowest electromagnetic eigenmodes of the device with the other two qubits defined as parallel LC impedances, Z_{JJi}=((iωLᵢ)⁻¹+iωCᵢ)⁻¹. In the following section, we use these eigenmode solutions to estimate the Hamiltonian matrix elements corresponding to qubit-qubit mode and qubit-coupler mode coupling strengths. We will differentiate between this modal coupling and direct capacitive coupling in the final part of this section, where we calculate the direct charge-charge interaction matrix elements.

### B. Energy Participation Ratios and Quantization

To extract the coupling matrix elements between the qubits in our microwave device layout, we employ the energy participation ratio (EPR) method developed by Minev [24]. This approach goes beyond the larger family of black box quantization methods, where the Hamiltonian describing a collection of Josephson junction-based qubits interacting with any number of harmonic modes separates into linear and nonlinear terms [25,26].

One can relate the modal decomposition of the classical electromagnetic response, e.g., impedance, admittance, or electromagnetic energies, with the linear and nonlinear parts of the Hamiltonian. Additional inputs describing the Josephson junction energy scales, E_{J} and E_{c}, complete the model. The total Hamiltonian, accounting for M modes, under the rotating wave approximation, reads

$$H = \text{?} \qquad ( 18 )$$

$$\text{?} / ℏ = {\sum }_{m = 1}^{M} {ω}_{m} {a}_{m}^{†} {a}_{m} \qquad ( 19 )$$

$$\begin{matrix}\text{?} / ℏ = - {\sum }_{m = 1}^{M} ( {Δ}_{m} {a}_{m}^{†} {a}_{m} + \frac{1}{2} \text{?} {a}_{m}^{†2} {a}_{m}^{2} ) \\ + \frac{1}{2} \text{?} {χ}_{mn} {a}_{m}^{†} {a}_{m} \text{?} ,\end{matrix} \qquad ( 20 )$$

$$\text{?} \text{indicates text missing or illegible when filed}$$

where we define the Lamb shifts Δₘ, cross-Kerr coefficients χₘₙ, and anharmonicities am as

$${Δ}_{m} = \frac{1}{2} \text{?} {χ}_{mn} \qquad ( 21 )$$

$${χ}_{mn} = - {\sum }_{j ∈ J} \frac{1}{2} \frac{{ℏω}_{m} {ω}_{n}}{4 \text{?}} \qquad ( 22 )$$

$${α}_{m} = \frac{1}{2} {χ}_{mm} . \qquad ( 23 )$$

$$\text{?} \text{indicates text missing or illegible when filed}$$

Table III gives a summary of the cross- and self-Kerr (an-harmonicities) coefficients along with the three lowest electromagnetic modes of the device as extracted with the pyEPR Python package [24,27]. The eigenfrequencies and quality factors in the first two columns of Table III follow from the HFSS eigenmode solutions. Diagonal entries of x are scaled by ½ to denote the anharmonicities from Eq. (23).

TABLE III
Extracted matrix elements from energy participation ratio
calculations for values of R₁₂, C₁₂ in the fully depleted (d) and
fully conducting(c) limits of the 2DEG

| | ω/2π | | | | |
|---|---|---|---|---|---|
| Mode Index | [GHz] | Q | χ/2π [MHz] | | |
| 1 (d) | 5.667 | 4.5E8 | 226 | 62.5 | 0.965 |
| 2 (d) | 5.838 | 1.3E9 | 62.5 | 226 | 1.11 |
| 3 (d) | 8.614 | 1.8E13 | 0.965 | 1.11 | 0.002 |
| 1 (c) | 5.669 | 4.5E8 | 223 | 67.1 | 0.974 |
| 2 (c) | 5.840 | 1.3E9 | 67.1 | 223 | 1.12 |
| 3 (c) | 8.612 | 1.8E13 | 0.974 | 1.12 | 0.002 |

### C. Extraction of the Exchange Interaction

To compute a more precise estimate of the charge-charge interaction between the transmon qubits in our HFSS model, we consider the capacitance matrix associated with a persistent current or flux qubit following the derivation by Orlando et al. [28]. For details on the derivation of the capacitance matrix, see Annex B. The Hamiltonian for the coupled two transmons, written in terms of the Josephson junction phases φᵢ and node charges [symbol] is given by

$$H = \frac{1}{2} {Q}^{T} {C}^{- 1} Q + U ( φ ) \qquad ( 24 )$$

$$U ( φ ) = \text{?} ( 1 - cos \text{?} ) \qquad ( 25 )$$

$$C = ( \begin{matrix}{C}_{1} + {C}_{3} & - {C}_{3} \\ - {C}_{3} & {C}_{2} + {C}_{2}\end{matrix} ) . \qquad ( 26 )$$

$$\text{?} \text{indicates text missing or illegible when filed}$$

Eq. (24) gives the charge-charge matrix elements as one half the entries of the inverse of the capacitance matrix, C⁻¹/2. We numerically inverted C in Eq. (26) using values for C₁, C₂ obtained from Eq. (B6) and C₃=C₁₂ (V_{g}) in the depleting and conducting limits.

FIG. 4 shows a capacitance matrix computed with the COMSOL electrostatics interface for (a) the fully depleted and (b) fully conducting limits of the 2DEG, and a conductance matrix computed with the COMSOL electric currents interface for (c) the fully depleted and (d) fully conducting limits of the 2DEG. Vertical and horizontal axes labels correspond to terminal indices in FIG. 1. The tuning ratio between the conducting and depleted 2DEG is given by r=C_{12,conducting}/C_{12,depleted}=160.

Table IV summarizes these results, reproducing the tuning ratio observed in FIG. 4, r≈160. Table IV gives charge-charge (exchange) interaction matrix elements in the (d) depleting and (c) conducting limits of the 2DEG coupler.

TABLE IV
Charge-charge (exchange) interaction matrix elements in the
(d) depleting and (c) conducting limits of the 2DEG coupler

| Qubit Index | Matrix Elements | [MHz] |
|---|---|---|
| 1 (d) | 226 | 0.0005 |
| 2 (d) | 0.0005 | 226 |
| 1 (c) | 226 | 0.079 |
| 2 (c) | 0.079 | 226 |

We emphasize here that the off-diagonal charge-charge interaction matrix elements give a more accurate description of the coupling between the qubits mediated by the 2DEG coupler than the EPR calculations. Although the energy scale for the coupling is small relative to the anharmonicities, this is a desirable feature, as the coupling is dominated by the small, tunable capacitance C₁₂.

### IV. CONCLUSION

We simulated a 2DEG-based, voltage-controlled tunable coupler compatible with superconducting qubits. The estimated tuning ratio of ≈160 and high impedance of the off state, serve as an excellent candidate for coupling qubits. Our HFSS simulations and subsequent capacitance matrix inversion analysis suggest that the coupling matrix elements exhibit the same range of tunability and loss estimates show the gate dielectric limits the coherence of the qubit, not the III-V semiconductors. These results, coupled with the benefit of second order compared with first order sensitivity to charge noise rather than flux noise, give us confidence that voltage-controlled coupling elements of the form developed here have the potential to supplant their inductive counterparts as the de facto coupler-of-choice in superconducting qubit systems.

### ANNEX A. III-V TERNARY ALLOY PARAMETER CALCULATIONS

Following the standard linear and quadratic interpolation schemes for III-V ternary alloys AₓB₁₋ₓC, with composition parameter x and in terms of experimentally measured values of their binary constituents, AB and BC, we have the lattice constant α, energy gap E^{g}, and effective mass at the Γ point m^{Γ*} as [29]

$$\text{?} C = x \text{?} + ( 1 - x ) \text{?} , \qquad ( A1 )$$

$$\text{?} C = {xE}_{AC} + ( 1 - x ) {E}_{BC} + x ( 1 - x ) {E}_{AB} , \qquad ( A2 )$$

$$\text{?} = {xm}_{AC}^{Γ} + ( 1 - x ) {m}_{BC}^{Γ} + x ( 1 - x ) {m}_{AB}^{Γ} . \qquad ( A3 )$$

$$\text{?} \text{indicates text missing or illegible when filed}$$

Similarly, the hole effective masses follow from a quadratic interpolation scheme of the AB, AC binary components as computed from a spherical band approximation of the valence band edge [29]

$$\text{?} = \text{?} , \qquad ( A4 )$$

$${m}_{p , c} = \text{?} , \qquad ( A5 )$$

$$\text{?} C = x \text{?} + ( 1 - x ) \text{?} , \qquad ( A6 )$$

$$\text{?} C = x \text{?} + ( 1 - x ) \text{?} \qquad ( A7 )$$

$$\text{?} \text{indicates text missing or illegible when filed}$$

We recognize that the spherical band approximation may not apply to the III-V materials in our study, but it gives an estimate for density of states and conduction band effective masses that are inputs to the COMSOL Semiconductor Module materials models.

To estimate the conduction band offsets between the InₓAl₁₋ₓAs and InₓGa₁₋ₓAs layers, we followed another interpolation scheme that computes the absolute duction band edges E_{c} directly

$${E}_{c} = {E}_{v , avg} + \frac{{Δ}_{0}}{3} + {E}_{g} + Δ {E}_{c}^{hy} , \qquad ( A8 )$$

$$Δ \text{?} = {E}_{c}^{B} = {E}_{c}^{A} , \qquad ( A9 )$$

$$\text{?} \text{indicates text missing or illegible when filed}$$

where E_{v,avg} is the average valence band edge, Δ₀ is the spin-orbit splitting in the absence of strain, E_{g} is the band gap energy, and

$$Δ {E}_{c}^{hy}$$

is the shift or the conduction band edge due to hydrostatic strain.

These parameters are calculated from the following expressions with coefficients Cᵢⱼ read off from Table III compiled by Krijn [30].

$${E}_{v , avg} = {\sum }_{i = 1}^{2} \text{?} ( {E}_{v , avg} ) {x}^{i} , \qquad ( A10 )$$

$${Δ}_{0} = {\sum }_{i = 1}^{2} \text{?} ( {Δ}_{0} ) {x}^{i} , \qquad ( A11 )$$

$$Δ \text{?} = \frac{Δ a ( x )}{a ( x )} {\sum }_{i = 0}^{1} \text{?} ( Δ {E}_{c}^{hy} ) {x}^{i} , \qquad ( A12 )$$

$$Δ a ( x ) = {a}_{0} - a ( x ) . \qquad ( A 13 )$$

$$\text{?} \text{indicates text missing or illegible when filed}$$

### ANNEX B. CHARGE MATRIX DERIVATION

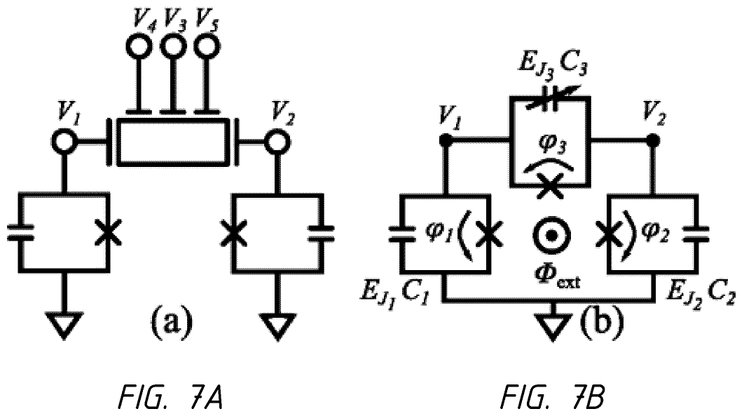

FIGS. 7A and 7B illustrate a circuit model for (FIG. 7A) the total 2DEG coupler with gates and a pair of transmon qubits, compared with (FIG. 7B) the simplified circuit used in the derivation of the charge matrix. The directions of the phases across the Josephson junctions are consistent with the conventions chosen by Orlando et al. for ease of comparison [28]. The labeling of the voltage nodes Vᵢ is used where nodes 1 and 2 correspond to source and drain terminals, and nodes 3-5 refer to the gate terminal.

Starting from the two transmon circuit coupled by a voltage-controlled Josephson junction (our 2DEG coupler) in FIG. 7B, with phases φ1, φ2, φ3 referring to the left, right, and coupling junctions, respectively, we have

$${φ}_{1} - {φ}_{2} + {φ}_{3} = - 2 {πΦ}_{ext} , \qquad ( B1 )$$

where φₑₓₜ is the flux threading the loop formed by the three Josephson junctions as in a typical flux qubit circuit.

For finite φₑₓₜ, the potential energy U is given by

$$\begin{matrix}U ( φ ) = {\sum }_{j} \text{?} ( 1 - cos {φ}_{j} ) \\ = \text{?} ( 1 - cos {φ}_{1} ) + \text{?} ( 1 - cos {φ}_{2} ) \\ + \text{?} ( 1 - cos ( {φ}_{2} - {φ}_{1} + 2 {πΦ}_{ext} ) )\end{matrix} , \qquad ( B2 )$$

$$\text{?} \text{indicates text missing or illegible when filed}$$

with the signs on the phases following FIG. 7B, preserving the conventions chosen in [28] and we order the phases in a single column vector as

$$φ = ( \begin{matrix}{φ}_{1} \\ {φ}_{2}\end{matrix} ) . \qquad ( B3 )$$

Setting φₑₓₜ=0, we compute the kinetic energy T by using the Josephson equation relating the voltages at nodes with k={1, 2}, Vₖ=(φ₀/2π)·φₖ and the definition of T in terms of φk

$$\begin{matrix}T = \frac{1}{2} ( {C}_{1} {V}_{1}^{2} + {C}_{2} {V}_{2}^{2} + {C}_{3} {V}_{3}^{2} ) \\ = \frac{1}{2} ( {C}_{1} \text{?} + {C}_{2} \text{?} + {{C}_{3} ( \text{?} - \text{?} )}^{2} ) \\ = \frac{1}{2} {( \frac{{Φ}_{0}}{2 π} )}^{2} \text{?} C \text{?}\end{matrix} , \qquad ( B4 )$$

$$\text{?} \text{indicates text missing or illegible when filed}$$

and reading off the capacitance matrix

$$C = ( \begin{matrix}{C}_{1} + {C}_{3} & - {C}_{3} \\ - {C}_{3} & {C}_{2} + {C}_{2}\end{matrix} ) . \qquad ( B5 )$$

Relating the total capacitances (both the intrinsic junction and external capacitance, commonly referred to as C_{Σ} [31]) shunting the junctions, C₁, C₂, to the anharmonicities extracted from the EPR calculations, we have, from the asymptotic expressions derived by Koch et al. [7]

$${C}_{k} = \frac{{e}^{2}}{2 {E}_{C}} ≃ - \frac{{e}^{2}}{2 {α}_{k}} \qquad ( B6 )$$

and we take C₃=C₁₂(V_{g}), the gate voltage-dependent capacitance across the 2DEG coupler.

The classical Lagrangian and Hamiltonian are associated with the kinetic and potential energies above, these then read

$$\begin{matrix}\text{?} ( φ , \text{?} ) = T - U \\ = \frac{1}{2} {( \frac{\text{?}}{2 π} )}^{2} \text{?} C \text{?} \\ - {\sum }_{j} \text{?} ( 1 - cos {φ}_{j} )\end{matrix} \qquad ( B7 )$$

$$\begin{matrix}\text{?} = {P}^{T} φ - \text{?} \\ = \frac{1}{2} {Q}^{T} {C}^{- 1} Q + U ( φ )\end{matrix} \qquad ( B8 )$$

$$\text{?} = \frac{\partial \text{?}}{\partial \text{?}} = {( \frac{\text{?}}{2 π} )}^{2} C \text{?} , Q = \frac{2 π}{\text{?}} P \qquad ( B9 )$$

$$\text{?} \text{indicates text missing or illegible when filed}$$

We take the form of the quantized Hamiltonian to be the same as the classical one in Eq. (B8) with classical variables promoted to operators, and identify the charge-charge matrix elements as C^{-1/2}.

### REFERENCES

[1] Y. Lu, S. Chakram, N. Leung, N. Earnest, R. K. Naik, Z. Huang, P. Groszkowski, E. Kapit, J. Koch, and D. I. Schuster, “Universal stabilization of a parametrically coupled qubit,” Phys. Rev. Lett. 119, 150502 (2017).
[2] Z. Huang, Y. Lu, E. Kapit, D. I. Schuster, and J. Koch, “Universal stabilization of single-qubit states using a tunable coupler,” Phys. Rev. A 97, 062345 (2018).
[3] F. Arute, K. Arya, R. Babbush, D. Bacon, J. C. Bardin, R. Barends, R. Biswas, S. Boixo, F. G. S. L. Brandao, D. A. Buell, B. Burkett, Y. Chen, Z. Chen, B. Chiaro, R. Collins, W. Courtney, A. Dunsworth, E. Farhi, B. Foxen, A. Fowler, C. Gidney, M. Giustina, R. Graff, K. Guerin, S. Habegger, M. P. Harrigan, M. J. Hartmann, A. Ho, M. Hoffmann, T. Huang, T. S. Humble, S. V. Isakov, E. Jeffrey, Z. Jiang, D. Kafri, K. Kechedzhi, J. Kelly, P. V. Klimov, S. Knysh, A. Korotkov, F. Kostritsa, D. Landhuis, M. Lindmark, E. Lucero, D. Lyakh, S. Mandrà, J. R. McClean, M. McEwen, A. Megrant, X. Mi, K. Michielsen, M. Mohseni, J. Mutus, O. Naaman, M. Neeley, C. Neill, M. Y. Niu, E. Ostby, A. Petukhov, J. C. Platt, C. Quintana, E. G. Rieffel, P. Roushan, N. C. Rubin, D. Sank, K. J. Satzinger, V. Smelyanskiy, K. J. Sung, M. D. Trevithick, A. Vainsencher, B. Villalonga, T. White, Z. J. Yao, P. Yeh, A. Zalcman, H. Neven, and J. M. Martinis, “Quantum supremacy using a programmable superconducting processor,” Nature 574, 505-510 (2019).
[4] R. Barends, C. M. Quintana, A. G. Petukhov, Y. Chen, D. Kafri, K. Kechedzhi, R. Collins, O. Naaman, S. Boixo, F. Arute, K. Arya, D. Buell, B. Burkett, Z. Chen, B. Chiaro, A. Dunsworth, B. Foxen, A. Fowler, C. Gidney, M. Giustina, R. Graff, T. Huang, E. Jeffrey, J. Kelly, P. V. Klimov, F. Kostritsa, D. Landhuis, E. Lucero, M. McEwen, A. Megrant, X. Mi, J. Mutus, M. Neeley, C. Neill, E. Ostby, P. Roushan, D. Sank, K. J. Satzinger, A. Vainsencher, T. White, J. Yao, P. Yeh, A. Zalcman, H. Neven, V. N. Smelyanskiy, and J. M. Martinis, “Diabatic gates for frequency-tunable superconducting qubits,” Phys. Rev. Lett. 123, 210501 (2019).
[5] K. Sardashti, M. C. Dartiailh, J. Yuan, S. Hart, P. Gumann, and J. Shabani, “Voltage-tunable superconducting resonators: a platform for random access quantum memory,” arXiv e-prints, arXiv:2006.08683 (2020), arXiv:2006.08683 [quant-ph].
[6] L. Casparis, N. J. Pearson, A. Kringhøj, T. W. Larsen, F. Kuemmeth, J. Nygård, P. Krogstrup, K. D. Petersson, and C. M. Marcus, “Voltage-controlled superconducting quantum bus,” Phys. Rev. B 99, 085434 (2019).
[7] J. Koch, T. M. Yu, J. Gambetta, A. A. Houck, D. I. Schuster, J. Majer, A. Blais, M. H. Devoret, S. M. Girvin, and R. J. Schoelkopf, “Charge-insensitive qubit design derived from the Cooper pair box,” Phys. Rev. A 76, 042319 (2007).
[8] W. D. Oliver and P. B. Welander, “Materials in superconducting quantum bits,” MRS Bulletin 38, 816-825 (2013).
[9] T. W. Larsen, K. D. Petersson, F. Kuemmeth, T. S. Jespersen, P. Krogstrup, J. Nygård, and C. M. Marcus, “Semiconductor-nanowire-based superconducting qubit,” Phys. Rev. Lett. 115, 127001 (2015).
[10] C. R. H. McRae, A. McFadden, R. Zhao, H. Wang, J. L. Long, T. Zhao, S. Park, M. Bal, C. J. Palmstrøm, and D. P. Pappas, “Dielectric loss in epitaxial Al/GaAs/Al trilayers for superconducting circuits,” arXiv e-prints, arXiv:2009.10101 (2020), arXiv:2009.10101 [physics.app-ph].
[11] M. Scigliuzzo, L. E. Bruhat, A. Bengtsson, J. J. Burnett, A. F. Roudsari, and P. Delsing, “Phononic loss in superconducting resonators on piezoelectric substrates,” New Journal of Physics 22, 053027 (2020).
[12] W. Mayer, J. Yuan, K. S. Wickramasinghe, T. Nguyen, M. C. Dartiailh, and J. Shabani, “Superconducting proximity effect in epitaxial Al—InAs heterostructures,” Applied Physics Letters 114, 103104 (2019), https://doi.org/10.1063/1.5067363.
[13] R. C. Bialczak, M. Ansmann, M. Hofheinz, M. Lenander, E. Lucero, M. Neeley, A. D. O'Connell, D. Sank, H. Wang, M. Weides, J. Wenner, T. Yamamoto, A. N. Cleland, and J. M. Martinis, “Fast Tunable Coupler for Superconducting Qubits,” Phys. Rev. Lett. 106, 060501 (2011).
[14] “The Semiconductor Module User's Guide,” https://doc.comsol.com/5.5/docserver/#!/com.comsol.help.semicond/html_SemiconductorModuleManual.html (2020).
[15] K. Hirabayashi, “Dielectric Theory of the Barrier Height at Metal-Semiconductor and Metal-Insulator Interfaces,” Phys. Rev. B 3, 4023-4025 (1971).
[16] B. Streetman and S. Banerjee, “Energy bands and charge carriers in semiconductors,” in Solid State Electronic Devices (Pearson, 2015) Chap. 5, pp. 238-243.
[17] K. S. Wickramasinghe, W. Mayer, J. Yuan, T. Nguyen, L. Jiao, V. Manucharyan, and J. Shabani, “Transport properties of near surface InAs two-dimensional heterostructures,” Applied Physics Letters 113, 262104 (2018), https://doi.org/10.1063/1.5050413.
[18] M. G. Ancona, “Density-gradient theory: a macroscopic approach to quantum confinement and tunneling in semiconductor devices,” Journal of Computational Electronics 10, 65-97 (2011).
[19] R. Kim, X. Wang, and M. Lundstrom, “Notes on Fermi-Dirac Integrals,” (2019), arXiv:0811.0116 [cond-mat.mes-hall].
[20] “The AC/DC Module User's Guide,” https://doc.comsol.com/5.5/docserver/#!/com.comsol.help.acdc/html_ACDCModuleManual.html (2020).
[21] J. Wenner, R. Barends, R. C. Bialczak, Y. Chen, J. Kelly, E. Lucero, M. Mariantoni, A. Megrant, P. J. J. O'Malley, D. Sank, A. Vainsencher, H. Wang, T. C. White, Y. Yin, J. Zhao, A. N. Cleland, and J. M. Martinis, “Surface loss simulations of superconducting coplanar waveguide resonators,” Applied Physics Letters 99, 113513 (2011), https://doi.org/10.1063/1.3637047.
[22] C. Wang, C. Axline, Y. Y. Gao, T. Brecht, Y. Chu, L. Frunzio, M. H. Devoret, and R. J. Schoelkopf, “Surface participation and dielectric loss in superconducting qubits,” Applied Physics Letters 107, 162601 (2015), https://doi.org/10.1063/1.4934486.
[23] D. Li, J. Gao, J. E. Austermann, J. A. Beall, D. Becker, H. Cho, A. E. Fox, N. Halverson, J. Henning, G C. Hilton, J. Hubmayr, K. D. Irwin, J. Van Lanen, J. Nibarger, and M. Niemack, “Improvements in Silicon Oxide Dielectric Loss for Superconducting Microwave Detector Circuits,” IEEE Transactions on Applied Superconductivity 23, 1501204-1501204 (2013).
[24] Z. K. Minev, “Catching and Reversing a Quantum Jump Mid-Flight,” (2019), arXiv:1902. 10355 [quant-ph].
[25] S. E. Nigg, H. Paik, B. Vlastakis, G. Kirchmair, S. Shankar, L. Frunzio, M. H. Devoret, R. J. Schoelkopf, and S. M. Girvin, “Black-Box Superconducting Circuit Quantization,” Phys. Rev. Lett. 108, 240502 (2012).
[26] F. Solgun, D. W. Abraham, and D. P. DiVincenzo, “Blackbox quantization of superconducting circuits using exact impedance synthesis,” Phys. Rev. B 90, 134504 (2014).
[27] Z. K. Minev, Z. Leghtas, S. O. Mundhada, L. Christakis, I. M. Pop, and M. H. Devoret, “Energy-participation quantization of Josephson circuits,” arXiv e-prints, arXiv:2010.00620 (2020), arXiv:2010.00620 [quant-ph].
[28] T. P. Orlando, J. E. Mooij, L. Tian, C. H. van der Wal, L. S. Levitov, S. Lloyd, and J. J. Mazo, “Superconducting persistent-current qubit,” Phys. Rev. B 60, 15398-15413 (1999).
[29] S. Adachi, “III-V Ternary and Quaternary Compounds,” in Springer Handbook of Electronic and Photonic Materials, edited by S. Kasap and P. Capper (Springer International Publishing, Cham, 2017) pp. 725-741.
[30] M. P. C. M. Krijn, “Heterojunction band offsets and effective masses in III-V quaternary alloys,” Semiconductor Science and Technology 6, 27-31 (1991).
[31] D. Schuster, Circuit Quantum Electrodynamics, Ph.D. thesis, Yale University (2007).

1. A system comprising:
a pair of qubits comprising first and second qubits with a coupling strength defined therebetween; and
a capacitive coupling element comprising a plurality of gate terminals, wherein the capacitive coupling elements is coupled between the pair of qubits with a respective gate voltage defined at each of the plurality of gate terminals;
wherein the capacitive coupling element is configured to provide a capacitance responsive to the respective gate voltages at each of the plurality of gate terminals, and to adjust the capacitance in response to the respective gate voltages at each of the plurality of gate terminals; and
wherein the capacitive coupling element is configured to control the coupling strength between the first and second qubits by adjusting the capacitance.

2. The system of claim 1, wherein the capacitive coupling element comprises a fixed air-gap capacitor having a source terminal coupled to the first qubit and a drain terminal coupled to the second qubit.

3. The system of claim 2, wherein the fixed air-gap capacitor comprises one or more doped n-type regions separated from the source terminal and the drain terminal by one or more air-gap regions, wherein a width of the one or more doped n-type regions is greater than a width of the one or more air-gap regions.

4. (canceled)

5. The system of claim 1, wherein the capacitive coupling element is configured with an Indium-Arsenide (InAs)/Indium Gallium Arsenide (InGaAs) semiconductor heterostructure.

6. The system of claim 1, wherein the plurality of gate terminals comprises at least three gate terminals formed on a substrate, wherein at least one of the plurality of gate terminals comprises a layer of silicon dioxide and a layer of gold, or wherein a width of at least one of the plurality of gate terminals is greater than a height of said at least one gate terminal.

7-8. (canceled)

9. The system of claim 1, wherein the capacitive coupling element is formed on a substrate configured to control the coupling strength by adjusting the capacitance in response to an alternating-current (AC) field, wherein the respective gate voltages are defined by the AC field.

10. The system of claim 1, wherein the pair of qubits are configured as first and second transmon qubits, or as first and second flux qubits.

11. (canceled)

12. A quantum computing device having pairs of qubits configured in a two-dimensional layer of a multi-qubit architecture, the device further comprising:
a plurality of said pairs of qubits, each pair of qubits comprising:
first and second qubits with a coupling strength defined therebetween; and
a coupling element comprising a plurality of gate terminals coupled between the pair of qubits;
wherein a capacitance of the coupling element is responsive to gate voltages defined at the respective gate terminals; and
wherein the coupling elements are configured to control the coupling strength between the first and second qubits by adjusting the capacitance in response to the gate voltages defined at the gate terminals.

13. The device of claim 8, wherein the pairs of qubits define different three-dimensional cavities of the multi-qubit architecture.

14. The device of claim 8, wherein each coupling element is configured to control the coupling strength of the respective first and second qubits by adjusting the capacitance in response to an alternating-current (AC) field applied to the system to perform parametric operations, wherein the gate voltages at the gate terminals are defined by the applied AC field.

15. The device of claim 8, wherein the pairs of qubits and the respective coupling elements are configured in a single, two-dimensional layer of a logical qubit device.

16. The device of claim 8, wherein at least one first qubit of the plurality of pairs of qubits is configured as a solid-state qubit, and at least one second qubit of the plurality of qubits is configured as a two-dimensional or three-dimensional cavity coupled to the at least one solid-state qubit.

17. The device of claim 8, wherein coupling elements are configured to control the coupling strengths of the respective first and second qubits by adjusting the respective capacitances to route signals between the pairs of qubits.

18-19. (canceled)

20. The device of claim 12, wherein the coupling elements comprise fixed gap capacitors having source terminals coupled to the respective first qubit and drain terminals coupled to the respective second qubit, with doped regions separated from the source and drain terminals by gap regions.

21. A method comprising:
selecting gate voltages for a plurality of gate terminals of a coupling element,
wherein the coupling element is coupled between a pair of qubits comprising first and second qubits with a coupling strength defined therebetween,
wherein the coupling element is configured to provide a capacitance responsive to the gate voltages; and
controlling the coupling strength between the first and second qubits, wherein the coupling strength is responsive to adjusting the capacitance based on the gate voltages selected at the respective of gate terminals.

22. The method of claim 21, wherein the coupling element comprises a fixed gap capacitor having a source terminal coupled to the first qubit and a drain terminal coupled to the second qubit, with the plurality of gate terminals disposed between the source and drain terminals.

23. The method of claim 21, wherein:
the first qubit of the pair of qubits is configured as a solid-state qubit; and
the second qubit of the pair of qubits is configured as a two-dimensional or three-dimensional cavity coupled to the first qubit.

24. The method of claim 21, wherein selecting the gate voltages comprises applying alternating current (AC) fields to a plurality of instances of said pair of qubits arranged in a multi-qubit architecture, wherein the gate voltages at the respective gate terminals are defined by the applied AC fields.

25. The method of claim 24, further comprising routing signals among selected pairs of the qubits of the multi-qubit architecture, responsive to controlling the coupling strengths between the respective first and second qubits.

26. The method of claim 25, further comprising performing a parametric operation with the multi-qubit architecture, responsive to routing the signals.
